(19) United States
(12) Patent Application Publication
(10) Pub. No.: US 2012/0008419 A1
(43) Pub. Date: Jan. 12, 2012

(54) SEMICONDUCTOR MEMORY DEVICE AND METHOD OF OPERATING THE SAME

(76) Inventors: Joo Yun HA, Seoul (KR); Jae Kwan KWON, Gyeonggi-do (KR)

(21) Appl. No.: 13/178,895

(22) Filed: Jul. 8, 2011

(30) Foreign Application Priority Data
Jul. 9, 2010 (KR) 10-2010-0066522
Jun. 14, 2011 (KR) 10-2011-0057499

(51) Int. Cl. G11C 16/06

(52) U.S. Cl. 365/185.25

(57) ABSTRACT

A semiconductor memory device includes cells strings including memory cells and coupled between a common source line and bit lines, respectively, a peripheral circuit configured to store data in the memory cells or read data stored in the memory cells, a main voltage supply unit configured to generate operating voltages to be supplied to the peripheral circuit, a precharge voltage supply unit configured to generate a precharge voltage for precharging the bit lines, and a switching circuit configured to transfer the precharge voltage to the common source line and one of the bit lines when a bit line precharge operation is performed.

### CROSS-REFERENCE TO RELATED APPLICATION

Priority to Korean patent application numbers 10-2010-0066522 filed on Jul. 9, 2010 and 10-2011-0057499 filed on Jun. 14, 2011, the entire disclosures of which are incorporated by reference herein, are claimed.

### BACKGROUND

Exemplary embodiments relate a semiconductor memory device and a method of operating the same.

Semiconductor memory devices which can be electrically programmed and erased and can retain its data even without the supply of power are useful. In obtaining high-capacity memory devices capable of storing a large amount of data, the integration degree of memory cells is being increased. In increasing the integration degree of semiconductor devices, a NAND type memory device may be used where a plurality of memory cells are coupled in series to form a cell string, a memory block is formed of the plurality of cell strings, and a memory cell array is formed of the plurality of memory blocks.

In the semiconductor memory device, an erasure operation of erasing data is performed on a memory-block basis, where the erasure operation of the memory block is performed by supplying a high voltage to a well of the memory block and 0 V to word lines. Here, since the memory blocks of the semiconductor memory device share the same well, word lines of unselected memory blocks float so that they are not erased by voltage boosting.

### BRIEF SUMMARY

Exemplary embodiments relate to a semiconductor memory device and a method of operating the same, which reduce/avoid a bit line boosting effect by using the same voltage supplied through a common line as both a precharge voltage for a selected bit line and a voltage for precharging an unselected bit line in a Negative Erase Verify (hereinafter referred to as an ‘NEV’) operation for determining whether memory cells have normally been erased.

A semiconductor memory device according to an aspect of the present disclosure includes cells strings including memory cells and coupled between a common source line and bit lines, respectively, a peripheral circuit configured to store data in the memory cells or read data stored in the memory cells, a main voltage supply unit configured to generate operating voltages to be supplied to the peripheral circuit, a precharge voltage supply unit configured to generate a precharge voltage for precharging the bit lines and output the precharge voltage to a precharge node, and a switching circuit configured to transfer the precharge voltage of the precharge node to selected bit lines through the common source line and unselected bit lines when a bit line precharge operation is performed.

A semiconductor memory device according to another aspect of the present disclosure includes cell strings including memory cells and coupled between a common source line and bit lines, respectively; a peripheral circuit configured to program data into the memory cells, read data stored in the memory cells, or erase data stored in the memory cells; a main voltage supply unit configured to generate operating voltages to be supplied to the peripheral circuit; a precharge voltage supply unit configured to generate a precharge voltage for precharging the bit lines and output the precharge voltage to a precharge node; and a control logic configured to generate a control signal so that the precharge voltage of the precharge node is supplied to selected bit lines through the common source line and unselected the bit lines for an erasure verification operation when a memory block including the cells strings is erased.

A method of operating a semiconductor memory device according to further yet another aspect of the present disclosure includes performing a hard erase operation of a memory block; programming memory cells of a cell string coupled to a selected bit line by supplying a first voltage to the memory cells; coupling a common source line of the cell string to a voltage supply node; coupling an unselected bit line of the memory block to the voltage supply node and precharging the unselected bit line; coupling the cell string of the selected bit line to the common source line and precharging the selected bit line; and detecting threshold voltages of the memory cells by detecting a voltage of the selected bit line.

### BRIEF DESCRIPTION OF THE DRAWINGS

FIG. 1 shows a semiconductor memory device illustrating this disclosure;

FIG. 2 shows a page buffer coupled to a bit line selection unit and a memory block of FIG. 1;

FIG. 3 is a diagram illustrating an NEV operation in an operating of erasing the memory block of FIG. 2;

FIG. 4 is a simple circuit diagram showing a coupling relationship between a common source line coupled to an even bit line and a variable voltage coupled to an odd bit line;

FIG. 5 shows a circuit for supplying the variable voltage and voltage supplied to the common source line SL and used to precharge a bit line in the NEV operation; and

FIG. 6 is a time diagram of changes in the variable voltage VIRPWR when the bit line is precharged as shown in FIG. 5.

### DESCRIPTION OF EMBODIMENTS

Hereinafter, some exemplary embodiments of the present disclosure are described in detail with reference to the accompanying drawings. The figures are provided to allow those having ordinary skill in the art to understand the scope of the embodiments of the disclosure.

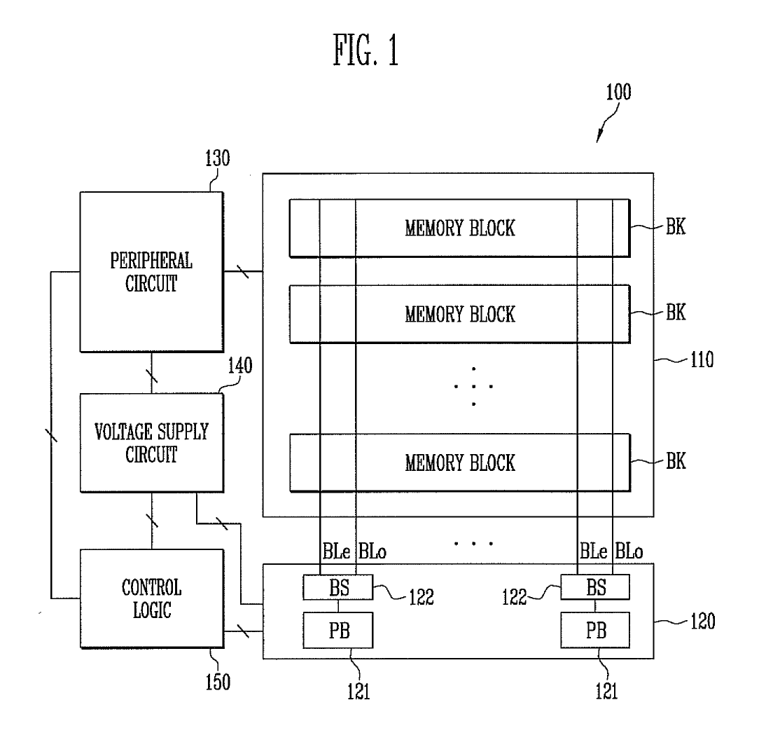

FIG. 1 shows a semiconductor memory device illustrating this disclosure.

Referring to FIG. 1, the semiconductor memory device 100 includes a memory cell array 110, a page buffer group 120, a peripheral circuit 130, a voltage supply circuit 140, and a control logic 150.

The memory cell array 110 includes a plurality of memory blocks BK. Each of the memory blocks includes cell strings that each include a plurality of memory cells. The structure of the cell string is described in detail below.

Each of the cell strings is coupled to a bit line. In an embodiment of this disclosure, bit lines are divided into even bit lines BLe and odd bit lines BLo and selected.

The page buffer group 120 includes a plurality of page buffers PB 121 and a plurality of a bit line selection unit BS 122. Each of the bit line selection unit 122 is coupled to a pair of the even bit line BLe and the odd bit line BLo. And each of the page buffers 121 is coupled to each of the bit line selection unit 122. The page buffer group 120 stores data to be programmed in memory cells coupled to bit lines or reads data stored in memory cells coupled to the bit lines.

The peripheral circuit 130 includes circuits for selecting the memory blocks BK of the memory cell array 110 and for performing a program, read, or erasure operation.

The voltage supply circuit 140 generates a program voltage Vpgm, a read voltage Vread, and an erase voltage Verasure for the program, read, and erasure operations and generates control voltages for controlling the page buffers 121.

The control logic 150 controls the operations of the page buffer group 120, the peripheral circuit 130, and the voltage supply circuit 140.

Interactions between cell strings, bit lines, and the page buffer are described in detail below.

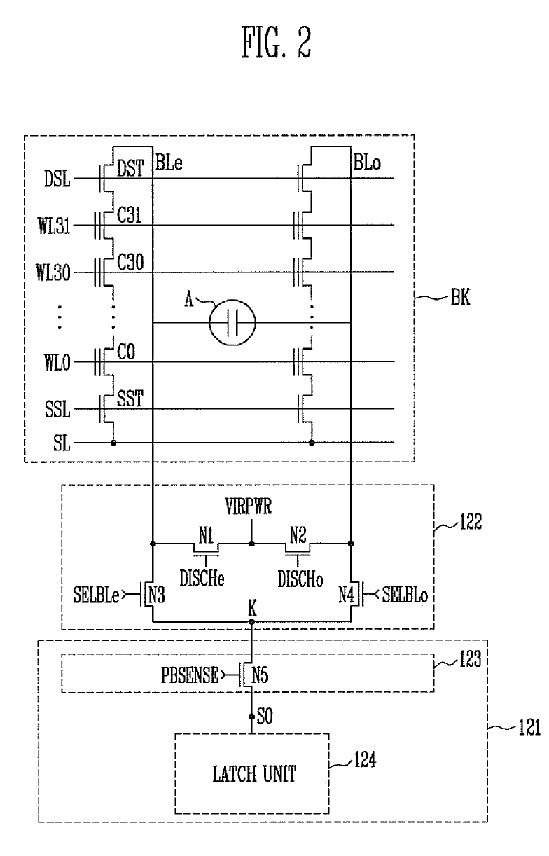

FIG. 2 shows a page buffer coupled to a bit line selection unit and a memory block of FIG. 1.

Referring to FIG. 2, the bit line selection unit 122 is coupled to a pair of even bit line BLe and odd bit line BLo of the memory block BK. And the page buffer 121 is coupled to the bit line selection unit 122

The cell strings of the memory block BK are coupled to the even bit line BLe and the odd bit line BLo, respectively.

Each cell string includes a drain select transistor DST, a source select transistor SST, and 0^{th} to 31^{st} memory cells C0 to C31.

The 0^{th} to 31^{st} memory cells C0 to C31 are coupled in series between the drain select transistor DST and the source select transistor SST.

A drain select line DSL is coupled to the gate of the drain select transistor DST, and a source select line SSL is coupled to the gate of the source select transistor SST.

The drain of the drain select transistor DST is coupled to the bit line, and the source of the source select transistor SST is coupled to a common source line SL.

0^{th} to 31^{st} word lines WL0 to WL31 are coupled to the respective gates of the 0^{th} to 31^{st} memory cells C0 to C31.

The bit line selection unit 122 selects the even bit line BLe or the odd bit line BLo and couples the selected bit line to a node K or precharges the even or odd bit line BLe or BLo using a variable voltage VIRPWR.

Furthermore, the page buffer 121 includes a sense unit 123, and a latch unit 124.

The sense unit 123 changes the voltage of a sense node SO according to voltage of the node K. The latch unit 124 includes latch circuits coupled to the sense node SO.

The bit line selection unit 122 includes first to fourth NMOS transistors N1 to N4. The sense unit 123 includes a fifth NMOS transistor N5.

The first and the second NMOS transistors N1 and N2 are coupled in series between the even bit line BLe and the odd bit line BLo. The variable voltage VIRPWR is supplied to the node of the first and the second NMOS transistors N1 and N2. The variable voltage VIRPWR changes from a power supply voltage to a ground voltage.

An even discharge signal DISCHe is inputted to the gate of the first NMOS transistor N1, and an odd discharge signal DISCHo is inputted to the gate of the second NMOS transistor N2.

The third NMOS transistor N3 is coupled between the even bit line BLe and the node K. An even bit line selection signal SELBLe is inputted to the gate of the third NMOS transistor N3.

The fourth NMOS transistor N4 is coupled between the odd bit line BLo and the node K. An odd bit line selection signal SELBLo is inputted to the gate of the fourth NMOS transistor N5.

The fifth NMOS transistor N5 is coupled between the node K and the sense node SO. A sense signal PBSENSE is inputted to the fifth NMOS transistor N5.

For a hard erase operation, the erase voltage Verasure is supplied to the well of a selected memory block BK including the cell strings, the drain select line DSL and the source select line SSL of the selected memory block BK float, 0 V is supplied to the word lines WL0 to WL31 of the selected memory block BK, and the word lines WL0 to WL31 of unselected memory blocks BK float.

Accordingly, the threshold voltages of the memory cells of the selected memory block B are erased to 0 V or lower.

By having memory cells with threshold voltages close to 0 V after being erased, inter-cell interference may be reduced in subsequent program operations. For this reason, after a hard erase operation for a memory block is performed, an NEV (Negative Erase Verify) operation is performed in order to make the threshold voltages of relevant memory cells that are lower than 0 V close to 0 V.

FIG. 3 is a diagram illustrating the NEV operation in the operating of erasing the memory block BK of FIG. 2.

The diagram of FIG. 3 is described with reference to FIG. 2.

Here, details of an NEV operation are well known in the art, and thus only those parts that are reasonably helpful in illustrating embodiments of this disclosure are described.

Referring to FIG. 3, in the NEV operation subsequent to the hard erase operation, the channel of the cell string coupled to a selected bit line BLe or BLo is precharged to a voltage inputted through the common source line SL, and unselected bit line BLe or BLo are precharged to the variable voltage VIRPWR.

A time interval from a time t1 to a time t2 in FIG. 3 is a reset time interval.

In this time interval, the even and odd discharge signals DISCHe and DISCHo, both having a high level, and the variable voltage VIRPWR of 0 V are supplied. Thus, the even and odd bit lines BLe and BLo are discharged.

In precharging the bit lines, the even discharge signal DISCHe changes to a low level, and the odd discharge signal DISCHo maintains a high level. Furthermore, the variable voltage VIRPWR rises to the power supply voltage Vcc.

Furthermore, the voltage of the common source line SL rises up to voltage VCCI.

0 V is supplied to word lines WL0 to WL31. The hard erase operation for the memory block BK is completed before the NEV operation is performed. Accordingly, the threshold voltages of the memory cells are lower than 0 V. In this state, when 0 V is supplied to word lines WL0 to WL31, the memory cells coupled thereto are turned on. At this time, although the threshold voltages of the memory cells are 0 V or lower, the program degrees of the memory cells are different according to their threshold voltages.

After the common source line SL starts to increase, 4.5 V is supplied to the drain select line DSL so that the cell string and the bit line are coupled. The voltage supplied to the common source line SL is not transferred to the cell string or the bit line because the source select line SSL has a voltage of 0 V.

Next, when the sense signal PBSENSE having a voltage of V1 is supplied in the time interval between the time t2 and a time t3, the even bit line BLe is fully discharged. The odd bit line BLo has been precharged prior to the time t3. When a program verification operation is performed, an unselected bit line remains precharged.

After the sense signal PBSENSE changes to a low level after the time t3, the source select transistor SST is turned on by supplying 4.5 V to the source select line SSL. Accordingly, the even bit line BLe starts being precharged to the voltage inputted to the common source line SL. A level of the voltage precharged by the even bit line BLe varies according to the threshold voltages of memory cells of a cell string. For example, when the threshold voltages of memory cells have −aV, a relevant bit line is precharged to about aV. When the threshold voltages of memory cells are lower than −aV, voltage precharged by a relevant bit line is higher than aV. At this time, the odd bit line BLo has been precharged to the power supply voltage Vcc of the variable voltage VIRPWR.

Next, the sense signal PBSENSE having a voltage of V2 is supplied at a time t7. The voltage V2 has a value (aV+Vth). Before the sense signal PBSENSE is supplied, the sense node SO is precharged to voltage of a high level. A precharge signal PRECH for precharging the sense node SO is not shown in FIG. 3.

Accordingly, if the even bit line BLe has been precharged to aV or a voltage lower than aV, the fifth NMOS transistor N5 is turned on, and thus the voltage of the sense node SO drops due to charge sharing. It can be determined whether the threshold voltages of memory cells are higher than or lower than −aV by detecting the dropped voltage of the sense node SO.

Meanwhile, when the voltage of the common source line SL is transferred to the even bit line BLe, the voltage of the odd bit line BLo is further boosted due to a coupling effect between the even bit line BLe and the odd bit line BLo, as shown in FIG. 3. The variable voltage VIRPWR may also be boosted by the voltage of the common source line SL.

In this case, the NEV operation may not be normally performed because the voltage of the odd bit line BLo and the variable voltage VIRPWR are boosted at the same time while the voltage of the even bit line BLe rises.

This feature occurs because the voltage supplied to the common source line SL differs from the voltage source of the variable voltage VIRPWR.

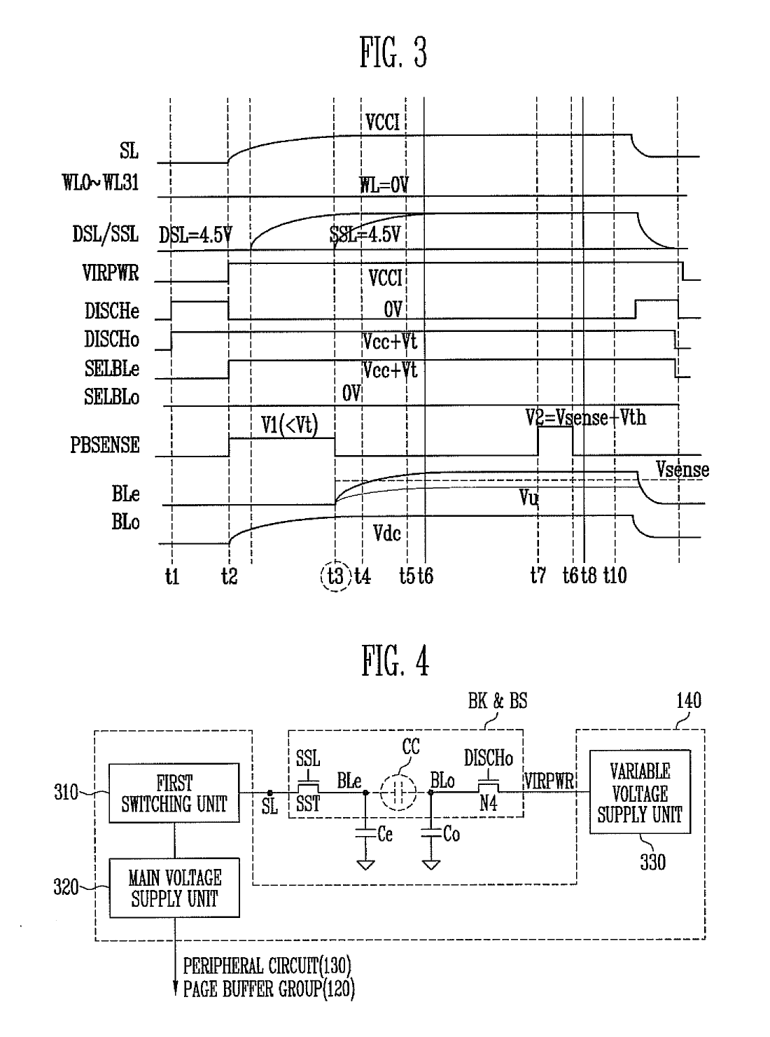

FIG. 4 is a simple circuit diagram showing a coupling relationship between the common source line coupled to the even bit line BLe and the variable voltage VIRPWR coupled to the odd bit line BLo.

FIG. 4 shows an equivalent circuit when the bit line is precharged by supplying an operating voltage during the NEV operation.

In FIG. 4, during the NEV operation, 0 V is supplied to the word lines WL0 to WL31, and 4.5 V is supplied to the drain select line DSL. Accordingly, the even bit line BLe is coupled to the common source line SL through the source select transistor SST coupled to the channel of the cell string.

The common source line SL is supplied with a voltage through a first switching unit 310. The voltage is supplied from the main voltage supply unit 320.

Here, the variable voltage VIRPWR, used to precharge the odd bit line BLo and received through the fourth NMOS transistor N4 of the page buffer 121 in FIG. 2, is supplied from a variable voltage supply unit 330 different from the main voltage supply unit 320.

The first switching unit 310, the main voltage supply unit 320, and the variable voltage supply unit 330 are included in the voltage supply circuit 140 and operated under the control of the control logic 150.

The voltage of the main voltage supply unit 320 is also supplied as the operating voltage for the page buffer group 120 and the peripheral circuit 130 of FIG. 1.

Capacitors Ce and Co are the parasitic capacitors of the even and odd bit lines BLe and BLo.

As shown in FIG. 4, the voltage supplied to the common source line SL and the variable voltage VIRPWR are supplied from the main voltage supply unit 320 and the variable voltage supply unit 330, respectively. Accordingly, a capacitive coupling through a coupling capacitor CC occurs between the even bit line BLe and the odd bit line BLo.

More specifically, a voltage of the odd bit line BLo precharged to the power supply voltage Vcc of the variable voltage VIRPWR is boosted by the voltage supplied to the even bit line BLe via the common source line SL.

In order to address such a feature, according to an embodiment of this disclosure, a circuit is constructed so that a common voltage source supplies a voltage as both a voltage for the common source line SL and the variable voltage VIRPWR through a common node (e.g., VBLSRC).

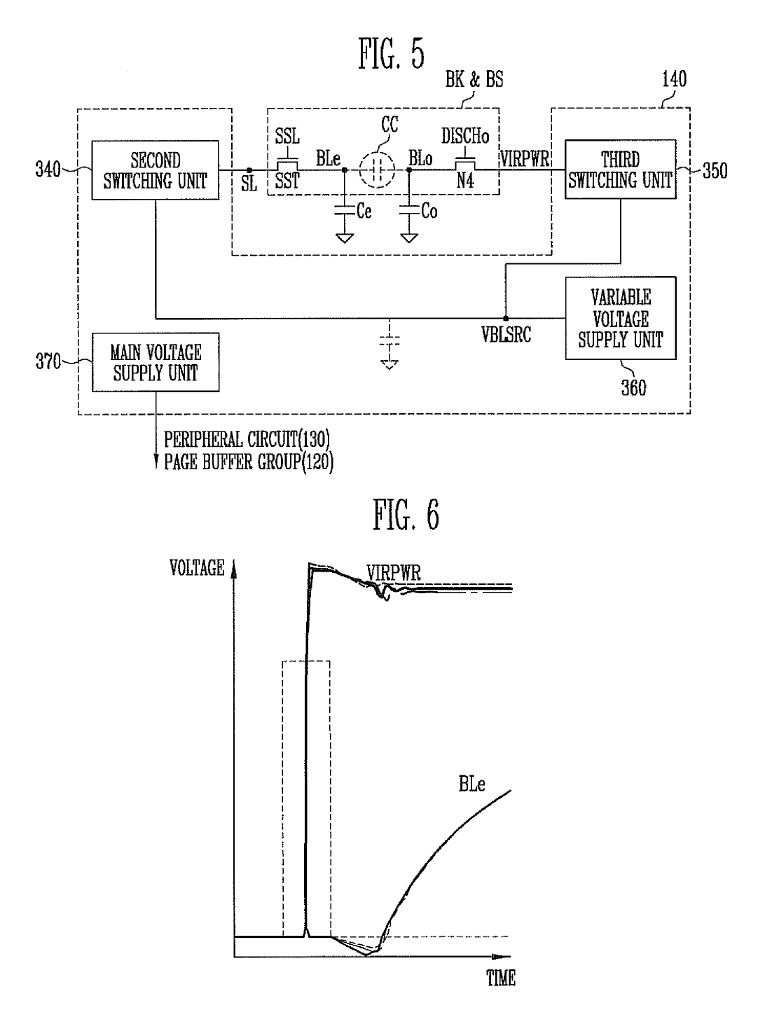

FIG. 5 shows a circuit for supplying a bit line precharge voltage according to an embodiment of this disclosure.

FIG. 5 shows a circuit for supplying the variable voltage VIRPWR and a voltage supplied to the common source line SL and used to precharge a bit line in the NEV operation.

Referring to FIG. 5, the circuit includes a second switching unit 340 for supplying the voltage to the common source line SL and a third switching unit 350 for supplying the variable voltage VIRPWR to the odd bit line BLo. The second and third switching units 340 and 350 are coupled to the variable voltage VIRPWR 360.

The circuit of FIG. 5 further includes a variable voltage supply unit 360 and a main voltage supply unit 370. The main voltage supply unit 370 does not supply a voltage to the second and third switching units 340 and 350, but supplies operating voltages to the page buffer group 120 and the peripheral circuit 130.

Accordingly, the voltage supplied to the common source line SL is not supplied from the main voltage supply unit 370, but supplied from a variable voltage supply unit 360.

The second and third switching units 340 and 350, the variable voltage supply unit 360, and the main voltage supply unit 370 are included in the voltage supply circuit 140 and operated under the control of the control logic 150.

The voltage outputted from the variable voltage supply unit 360 is supplied to a common node VBLSRC. The second and third switching units 340 and 350 are coupled in common to the common node VBLSRC.

The second and third switching units 340 and 350 are operated to supply a precharge voltage to the common source line SL and the odd bit line BLo. Here, a voltage of the source select line SSL is 0 V, and the odd discharge signal DISCHo has a voltage of 4.5 V. Accordingly, only the odd bit line BLo is precharged.

Next, when voltage of 4.5 V is supplied to the source select line SSL, the bit line BLe or BLo is precharged to the voltage at the common source line SL according to the threshold voltages of relevant memory cells. Although a coupling effect through the coupling capacitor CC between the even bit line BLe and the odd bit line BLo occurs, the voltage of the common source line SL and the variable voltage VIRPWR, which is supplied through one voltage supply line, offsets such a coupling effect so that a voltage of the odd bit line no is not boosted. Details of the process for precharging the bit line BLe or no, detecting voltage of the precharged bit line, and storing the detected voltage are not described as having been described above with reference to FIG. 3.

Since the variable voltage supply unit 360 is separated from the main voltage supply unit 350, the main voltage supply unit 350 may be uninfluenced by significant voltage shifts in the variable voltage supply unit 360.

As discussed above, the variable voltage VIRPWR and a voltage supplied to the common source line SL are supplied through the common node VBLSRC. Here, a voltage of an unselected bit line may be prevented from being boosted by a capacitive coupling effect when a selected bit line is precharged for an NEV operation.

FIG. 6 is a time diagram of changes in the variable voltage VIRPWR when the bit line is precharged as shown in FIG. 5.

In FIG. 6, the variable voltage VIRPWR remains constant without being boosted to a higher voltage during the precharge time of the even bit line BLe.

In the semiconductor memory device and the method of operating the same according to the embodiments of this disclosure, in an NEV operation for determining whether memory cells have been normally erased in an erasure operation, a voltage source supplies both a voltage to a selected bit line and a voltage to an unselected bit line. Accordingly, a bit line boosting effect may be avoided, and thus the NEV operation may be performed properly.

What is claimed is:

1. A semiconductor memory device, comprising:
cell strings including memory cells and coupled between a common source line and bit lines, respectively;
a peripheral circuit configured to store data in the memory cells or read data stored in the memory cells;
a main voltage supply unit configured to generate operating voltages to be supplied to the peripheral circuit;
a precharge voltage supply unit configured to generate a precharge voltage for precharging the bit lines and output the precharge voltage to a precharge node; and
a switching circuit configured to transfer the precharge voltage of the precharge node to selected bit lines through the common source line and unselected bit lines when precharge operation is performed.

2. The semiconductor memory device of claim 1, wherein the switching circuit comprises:
a first switching unit configured to transfer the precharge voltage of the precharge node to the common source line in response to a first control signal; and
a second switching unit configured to transfer the precharge voltage of the precharge node to a variable voltage supply node having the unselected bit lines coupled thereto in response to a second control signal.

3. The semiconductor memory device of claim 2, further comprising a control circuit configured to generate control signals for controlling operations of the peripheral circuit, the main voltage supply unit, and the precharge voltage supply unit and generate the first and the second control signals for the bit line precharge operation during an erasure verification operation.

4. A semiconductor memory device, comprising:
cell strings including memory cells and coupled between a common source line and bit lines, respectively;
a peripheral circuit configured to program data into the memory cells, read data stored in the memory cells, or erase data stored in the memory cells;
a main voltage supply unit configured to generate operating voltages to be supplied to the peripheral circuit;
a precharge voltage supply unit configured to generate a precharge voltage for precharging the bit lines and output the precharge voltage to a precharge node; and
a control logic configured to generate a control signal so that the precharge voltage of the precharge node is supplied to selected bit lines through the common source line and unselected bit lines for an erasure verification operation when a memory block including the cells strings is erased.

5. The semiconductor memory device of claim 4, further comprising a switching circuit configured to transfer the precharge voltage of the precharge node to the common source line the selected bit lines and the unselected bit lines when a bit line precharge operation is performed.

6. The semiconductor memory device of claim 5, wherein the switching circuit comprises:
a first switching unit configured to transfer the precharge voltage of the precharge node to the common source line in response to a first control signal; and
a second switching unit configured to transfer the precharge voltage of the precharge node to a variable voltage supply node having the second one of the bit lines coupled thereto in response to a second control signal.

7. The semiconductor memory device of claim 6, wherein:
when the first switching unit is turned on, the selected bit lines selected for the erasure verification operation are coupled to a cell strings coupled to the selected bit lines, from among the cell strings, and
when the second switching unit is turned on, the unselected bit lines is not coupled to a respective one of the cell strings.

8. A method of operating a semiconductor memory device, comprising:
performing a hard erase operation of a memory block;
programming memory cells of a cell string coupled to a selected bit line by supplying a first voltage to the memory cells;
coupling a common source line of the cell string to a voltage supply node;
coupling an unselected bit line of the memory block to the voltage supply node and precharging the unselected bit line;
coupling the cell string of the selected bit line to the common source line and precharging the selected bit line; and
detecting threshold voltages of the memory cells by detecting a voltage of the selected bit line.

9. The method of claim 8, wherein a precharged voltage of the precharged unselected bit line is not changed during a period of time that the threshold voltages of the memory cells are detected by detecting a voltage of the selected bit line.

10. The method of claim 8, wherein:
the programming of memory cells is performed by supplying the first voltage to the memory cells and raising the first voltage until the threshold voltages of the memory cells become equal to or higher than a set voltage, and
the programming of memory cells, the coupling of a common source line to a voltage supply node, the coupling of an unselected bit line to the voltage supply line, and the coupling of the cell string of the selected bit line to the common source line are repeatedly performed in sequence.

11. The method of claim 8, wherein in the coupling of an unselected line to the voltage supply line, the voltage supply node has a same voltage as a voltage of the voltage supply node in the coupling of a common source line to a voltage supply node.
